(19) United States
(12) Patent Application Publication
(10) Pub. No.: US 2010/0002792 A1
(43) Pub. Date: Jan. 7, 2010

(54) SYSTEM, APPARATUS AND METHOD FOR INTERLEAVING DATA BITS OR SYMBOLS

(75) Inventor: Seyed-Alireza Seyedi-Esfahani, Fairport, NY (US)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/522,942

(22) PCT Filed: Jan. 16, 2008
(86) PCT No.: PCT/IB2008/050161

§ 371 Date: Jul. 13, 2009

Related U.S. Application Data
(60) Provisional application No. 60/885,143, filed on Jan. 16, 2007.

(51) Int. Cl. H04K 1/10; G06F 12/00; H03M 13/17; G06F 11/10; H03M 13/23

(52) U.S. Cl. 375/260; 711/157; 714/788; 714/786; 714/E11.032; 711/E12.001

(57) ABSTRACT

A data transmission system respectively encodes successive bits representing information to be transmitted. An interleaver receives the bits from the encoder and interleaves the bits. The interleaver includes a memory and a memory read write controller configured to write the bits to the memory in accordance with a diagonal write pattern and to read the bits from the memory in a diagonal read pattern. A symbol mapper receives the interleaved bits and maps the encoded interleaved bits into symbols using a transmission format.

### CROSS REFERENCE TO RELATED APPLICATIONS

This application claims the benefit of prior filed, co-pending U.S. provisional application: Ser. No. 60/885,143, filed on Jan. 16, 2007.

### BACKGROUND OF THE INVENTION

1. Field of the Invention

This invention pertains to the field of data communications, and more particularly to a system and method of interleaving bits or symbols, suitable for deployment in a variety of transmission systems including, but not limited to, Orthogonal Frequency Division Modulation (OFDM) systems and Single Carrier Block Transmission (SCBT) systems.

2. Description of the Related Art

Data communication systems may be classified in a number of ways according to the transmission schemes they employ. One classification distinguishes between multi carrier communication systems and single carrier communication systems. OFDM is an example of a multi carrier communication scheme. SCBT is an example of a single carrier communication scheme.

The choice of transmission scheme depends on a variety of factors. For example, environmental characteristics of a communication channel can be a factor in choice of transmission scheme. Another factor influencing choice of transmission scheme is the performance criteria of communications systems used to transmit data over a communication channel. For some systems, OFDM will be better suited to meet system performance criteria. For other applications a single-carrier scheme will provide better system performance than a multiple carrier system.

For example, OFDM is often a good choice when peak-to-average power ratio of a transmitter is not a significant factor in system design. On the other hand, SCBT often provides better performance when peak-to-average power ratio is a consideration in system design. However, a standard single-carrier system typically requires an equalization scheme that is relatively expensive to implement. To ease the equalization requirement, single-carrier block single transmission (SCBT) schemes have been proposed recently. These SCBT schemes insert either zeros or a cyclic prefix to a block of data, just as is done in a conventional OFDM system.

In both OFDM and SCBT systems, at least one transmitter is configured to transmit information over a communication channel. Bits representing the information to be transmitted are converted to symbols by encoding the bits, for example in accordance with an error coding technique. The coded bits are mapped to symbols in accordance with a transmission scheme, for example, an OFDM or SCBT transmission scheme. The symbols are then transmitted over a communications channel.

The transmitted symbols are susceptible to noise and other channel disruptions. In many cases channel disruptions are bursty or that they occur in a specific pattern such as a periodic or near periodic pattern, that is, they occur over relatively short intervals, or in clusters. The bursts are typically followed by noise free intervals. Bursty channel conditions tend to result in increased errors in received decoded bits, especially when the transmitted symbols are in close proximity in time or space.

Forward error coding (FEC) techniques rely on redundancy in transmitted data to correct these errors. However, it is more difficult for an FEC decoder to take advantage of the redundancy inserted in the transmitted data when errors are due to bursts. Bursty disruptions are more likely to corrupt bits or symbols in close proximity, including the redundant bits provided in accordance with an error correction code

To mitigate the effects of bursty channel disruptions an interleaver is sometimes used at the transmitter. A corresponding de-interleaver is deployed in a receiver. Interleavers re-arrange the order of data to be transmitted before transmission. At the receiver, the original data order is restored and the information is recovered. As a result of the reordering operation, redundant bits or symbols that are close to each other before transmission are not close to each other when transmitted over the channel. Thus the likelihood that related data portions will be affected by bursty channel impairments and disruptions is decreased.

One conventional interleaving scheme (block interleaver) writes data to a rectangular memory in conventional vertical and horizontal patterns, for example, row by row, or column by column. The data is read from memory in a rectangular fashion in a vertical or horizontal order opposite the write order. At the receiver, received data is similarly written to, and read from memory in a vertical or horizontal order. This technique serves to interleave data to mitigate the effects of bursty channel conditions. However, this conventional technique suffers from drawbacks. For example, although the block interleaver rearranges the order of the data bits or symbols so that the data bits or symbols that were originally in each other's proximity will be farther placed, they will be placed in a periodic fashion. For example, consider three data bits/symbols that are consecutively placed prior to interleaving. After the interleaving these data symbols/bits will be placed with the exact separation N, where N is the width of the block interleaver.

This periodic nature of the block interleaver, leaves the data vulnerable to specific error and noise patterns. For example, when the noise appears in a periodic fashion, it is likely that all of the redundant symbols/bits will face a higher noise or error level. Both in SCBT and in OFDM data symbols can observe a periodic (or nearly periodic) noise characteristics, especially when the multipath channel consists of few paths.

Accordingly, it would be desirable to provide an interleaving scheme that can overcome the limitations of prior art interleavers by interleaving the bits or symbols in a fashion that do not have a periodic or nearly periodic characteristic, while maintaining low complexity.

### BRIEF DESCRIPTION OF THE DRAWINGS

These and other objects, features and advantages of the invention will be apparent from a consideration of the following detailed description of the invention considered in conjunction with the drawing figures, in which:

FIG. 1 illustrates functional blocks of a transmitter portion of a communication system employing a symbol interleaver according to an embodiment of the invention.

FIG. 2 illustrates an example format for a data packet 200 for use in transporting interleaved data according to an embodiment of the invention.

FIG. 3 illustrates functional blocks of a receiver portion of a communication system employing a symbol interleaver configured according to an embodiment of the invention.

FIG. 4 is a block diagram of an interleaver according to an embodiment of the invention.

FIG. 5 is a flow chart illustrating a method of interleaving data using the interleaver apparatus illustrated in FIG. 4 according to an embodiment of the invention.

FIG. 6 is a flow chart illustrating a method of interleaving data using the interleaver apparatus illustrated in FIG. 4 according to an embodiment of the invention.

FIG. 7 is a block diagram illustrating an alternative embodiment of the interleaver illustrated in FIG. 4 according to an embodiment of the invention.

FIG. 8 is a functional block diagram of a transmission system including an interleaver configured according to one embodiment of the invention.

FIG. 9 is a functional block diagram of a transmission system including an interleaver configured according to one embodiment of the invention.

FIG. 10 is a flow chart illustrating a method of interleaving data using the interleaver apparatus illustrated in FIG. 8 according to an embodiment of the invention.

FIG. 11 is a flow chart illustrating a method of interleaving data using the interleaver apparatus illustrated in FIG. 9 according to an embodiment of the invention.

FIG. 12 is a functional block diagram of an interleaver according to an embodiment of the invention suitable for use in data transmissions systems.

FIG. 13 is a functional block diagram of an interleaver suitable for use in transmissions systems according to one embodiment of the invention.

FIG. 14 is a functional block diagram of an interleaver suitable for use in transmissions systems according to an embodiment of the invention.

FIG. 15 is a functional block diagram of an interleaver suitable for use in transmissions systems according to embodiments of the invention.

### DETAILED DESCRIPTION OF THE PREFERRED EMBODIMENTS

In the following detailed description, for purposes of explanation and not limitation, example embodiments disclosing specific details are set forth in order to provide a thorough understanding of an embodiment according to the present teachings. However, it will be apparent to one having ordinary skill in the art having had the benefit of the present disclosure that other embodiments according to the present teachings that depart from the specific details disclosed herein remain within the scope of the appended claims.

Moreover, descriptions of well-known apparatus and methods may be omitted so as to not obscure the description of the example embodiments. Such methods and apparatus are intended to remain within the scope of the teachings herein.

### System Block Diagram

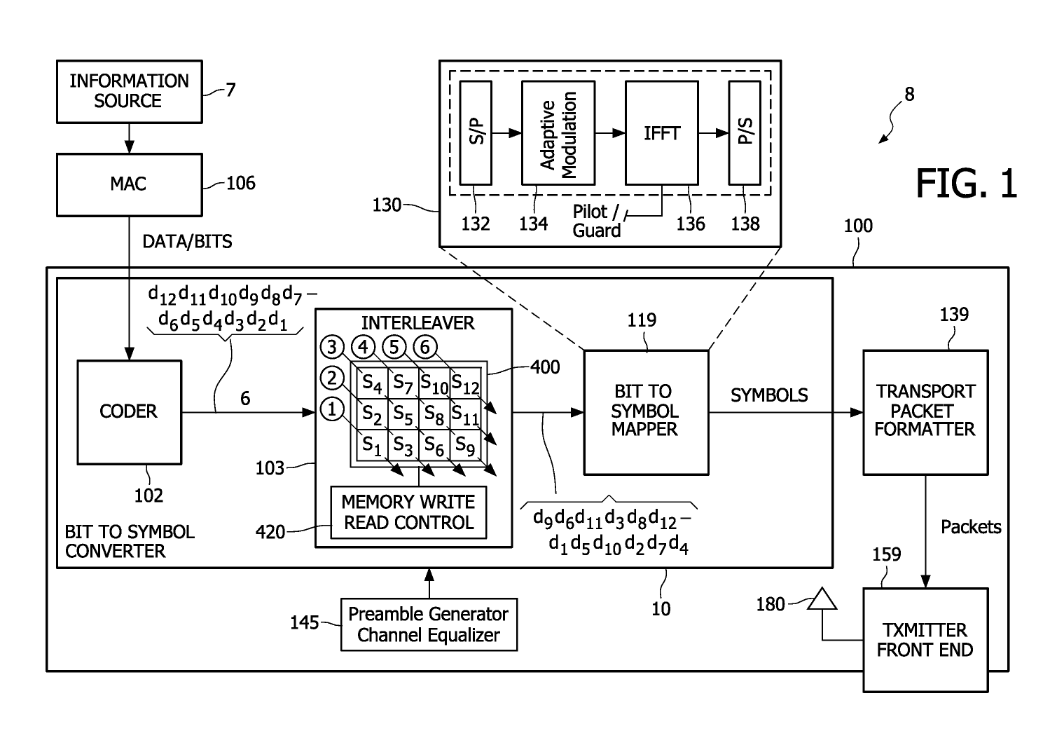

FIG. 1 is a functional block diagram of an example transmitter 100 comprising a communication system 1 suitable for implementing interleaving methods, systems and apparatus according to embodiments of the invention. The term “data” as used in this specification refers to information of any type as represented in electronic form, including, but not limited to video, audio, text, graphics, multimedia, voice, and command and control information. The term data is used herein to refer to binary digits (bits) as well as symbols, including symbols comprising binary digits.

As will be appreciated by those skilled in the art, the various functions shown in FIG. 1 and in other drawing figures herein are suitable for physical implementation using a software-controlled microprocessor, hard-wired logic circuits, and a variety of combinations thereof. For purposes of explanation, the drawing figures of this specification illustrate relevant functions as separate blocks. However, it will be readily understood implementation of the functions, while arranged for performing in accordance with the illustrated segregated functional blocks, may nonetheless be found integrated within a single subsystem or component and/or distributed across physical components and subsystems of a system without departing from the teachings of the present disclosure or the scope of the various embodiments of the invention disclosed.

### Data Transmitter 100

Data transmitter 100 comprises a data bit to symbol converter 10 coupled a transmitter front end via a packet formatter 139. A data source 5 provides data to be transmitted via an air channel by transmitter front end 159. Where multiple devices share access to a transmission medium, a medium access control (MAC) functional layer 106 provides medium access control for transmitter 100. Sequences of data bits representing the information to be transmitted are provided by MAC 106 to transmitter 100.

Data transmitter 100 illustrates a common transmitter configuration suitable for implementing either a multi-carrier transmission format (e.g., OFDM) or a single-carrier transmission format (e.g., SCBT).

### Bit to Symbol Converter

Bit to symbol converter 10 comprises a coder 102, an interleaver 10 and a bit to symbol mapper 119. The invention contemplates a variety of arrangements for coder 102, interleaver 10 and bit to symbol mapper 119. Only one of the various possible example configurations is illustrated in FIG. 1.

Bit to symbol converter 10 converts the bits sequences to corresponding sequences of symbols in accordance with a transmission scheme appropriate for the particular transmitter configuration of transmitter 100. For example, in one embodiment of the invention a multiple carrier transmission scheme is implemented by transmitter 100. When deployed in OFDM configurations, bit to symbol converter 10 is configured to provide symbols in accordance with an OFDM transmission scheme.

In another embodiment of the invention bit to symbol converter 10 is configured to provide symbols suitable for transmission by a single carrier transmission scheme. One example of a single carrier transmission scheme comprises a Single Carrier Block Transmission (SCBT) scheme. When deployed in a SCBT transmitter, bit to symbol converter 10 is configured to provide symbols in accordance with SCBT techniques.

Bit to symbol converter 10 provides symbol sequences to a packet formatter 139. Packet formatter 139 formats the symbol sequences and provides transport ready formatted packets, including the symbol sequences provided by bit to symbol converter 10 to transmitter front end 159. Transmitter front end 159 modulates the transmit packets from transmit packet formatter onto at least one carrier. The modulated signal is transmitted through an air medium by an antenna system 180.

### Coder

In the example configuration coder of FIG. 1 coder 102 receives bit sequences comprising information from data source 5 to be transmitted via transmitter 100. In operation coder 102 receives data, for example from a medium access control (MAC) layer 106. In some optional embodiments of the invention medium access control layer provides data including a packet header. Coder 102 encodes the data in accordance with a suitable coding technique. Examples of coding techniques suitable for implementation using coder 102 include, but are not limited to, forward error correction codes such as convolutional codes, block codes, concatenated code and various combinations thereof. In one embodiment of the invention coder 102 comprises a coder implementing a Forward Error Correction (FEC) scheme.

Forward error correction codes rely on insertion of redundant bits into the bit sequences provided by MAC 106. When transmitter 100 is deployed in a bursty transmission channel environment it is possible for redundant bits to be corrupted. Such corruption is known to result in errors when the transmitted signals are received and decoded.

For example, in an OFDM system it is more likely that symbols modulated on sub-carriers near a faded sub-carrier channel will be adversely affected by the same conditions that caused the fading in the faded subcarrier. SCBT systems, in particular in an SCBT employing Minimum Mean Square Error (MMSE) equalization, are likewise adversely affected by bursty channel conditions. After equalization, noise on symbols within a single block of SCBT data is correlated. Regardless of coding scheme, coder 102 provides coded bit sequences to an interleaver 103 to reduce the effects of bursty transmission channels.

### Interleaver

Interleaver 103 receives successive respective portions of data from coder 102. For example interleaver 103 receives successive bits comprising a first bit sequence at an interleaver 103 input. Interleaver 103 re-orders successive data portions comprising the first bit sequence. Interleaver 103 provides a second bit sequence at an output. The data portions comprising the second bit sequence are related to data portions comprising the first bit sequence by a diagonal read sequence and a diagonal write sequence implemented by interleaver 103.

In accordance with the embodiment of the invention illustrated in FIG. 1, interleaver 10 receives respective successive data portions in the form of coded bit sequences provided by coder 102. Interleaver 10 writes successive respective bits of the sequences to cells of memory 400 so as to define at least one diagonal of memory 400. In that manner interleaver 10 writes bits in accordance with a diagonal write sequence.

Interleaver 10 reads bits from memory 410 according to a diagonal read sequence to provide successive data portions at an interleaver output. The sequence of data portions provided at the output of interleaver 10 is different than the sequence of corresponding data portions received at the input of interleaver 10. In one embodiment of the invention this difference is characterized by an inverse diagonal relationship between the output sequence and the input sequence. In other words the diagonal read sequence is an inverse of the diagonal write sequence.

### Interleaver Detailed Functional Block Diagram

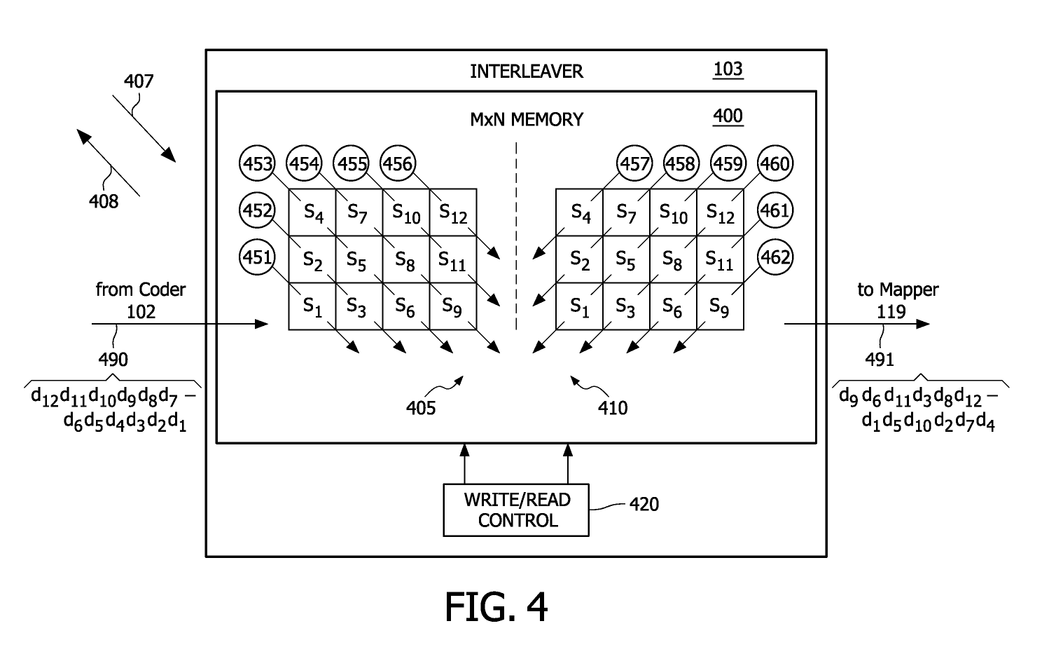

FIG. 4 illustrates further details of functional blocks of interleaver 103 comprising bit to symbol converter 10 of transmitter 100 as illustrated in FIG. 1. In this embodiment interleaver 103 comprises at least one M×N memory 400 coupled to a memory controller 420. M×N memory 400 comprises a plurality of storage cells arranged to provide a matrix of cells comprising M columns and N rows. The example memory 400 illustrated in FIG. 4 comprises three rows and four columns, i.e., a 4×3 memory. However, it will be understood that the number of rows and columns comprising memory 400 in the illustration of FIG. 4 is chosen for convenience of illustration and discussion. Practical implementations of interleavers according to various embodiments of the invention described herein may have greater numbers of rows and columns. The invention is not limited in implementation to any particular number of rows and columns comprising interleaver memory.

According to the example configuration illustrated in FIG. 4 interleaver 103 communicates with coder 102 to receive a first data sequence 490. First sequence 490 comprises successive respective data portions, for example, data portions S1 through S12. Twelve data portions are illustrated in the drawing figures herein for ease of discussion. However, it will be understood from reading this specification that the invention is not limited with respect to the number of data portions comprising data sequence 490.

Interleaver 103 provides a second sequence 491 of data portions at an interleaver output. Interleaver 103 is coupled to mapper 119 (best illustrated in FIG. 1) to provide the second sequence to mapper 119.

Write/Read controller 420 operates to write successive respective data portions of data sequence 490 to diagonals 451-456 of memory 400 in accordance with a diagonal write sequence. As a result of the write/read controller carrying out the diagonal write, memory 400 comprises an interleaver matrix. The interleaver matrix thus generated is illustrated twice in FIG. 4. The matrix is illustrated at 405 for purposes of discussion of a diagonal write operation, and again at 410 to describe a diagonal read operation.

When performing a diagonal write operation to generate matrix 405, memory controller 420 writes respective successive data portions of first sequence 490 to successive respective diagonals of memory 400 in accordance with a diagonal write pattern. In doing so, interleaver matrix 405 is generated. In the example of FIG. 4, first sequence 490 comprises successive respective data portions S₁ through S₁₂. Matrix 405 comprises data portions arranged such that adjacent data portions of first sequence 490 are not adjacent with respect to rows and columns of matrix 405. Instead adjacent portions of first sequence 490 are adjacent along diagonals 451-456 of matrix 405.

When performing a diagonal read operation memory controller 420 reads data portions from the interleaver matrix (as illustrated at 410) according to a diagonal read pattern to provide a second data sequence 491 comprising data portions at an output of interleaver 103. Second sequence 491 comprises interleaved data portions of first data sequence 490. In one embodiment of the invention a diagonal read pattern is an inverse pattern of a corresponding diagonal write pattern.

According to the example of FIG. 4 interleaver matrix 405/410 comprises (M+N)−1 diagonals, i.e., six diagonals for a 4×3 memory (indicated at 451-456 for a write operation illustration and at 457-462 for a read operation illustration). A diagonal read pattern is defined by an order in which diagonals are written during a write operation of write/read controller 420. A diagonal write pattern is defined by an order in which diagonals are read during a read operation of write/read controller 420.

A diagonal write direction is defined by the order in which cells of each diagonal are written. In one embodiment of the invention a first diagonal write direction is defined by writing respective successive data portions of data sequence 490 to diagonals 451-456. For each diagonal a first written cell is top-most left-most cell of the diagonal. The last written cell of the diagonal is the bottom-most, right-most cell of the diagonal. This embodiment generates interleaver matrix 405/410 illustrated in FIG. 4.

In another embodiment of the invention a second diagonal write direction is defined by writing successive respective data portions of data sequence 490 to diagonals 451 to 456. For each diagonal a first written cell is bottom most, right-most cell of the diagonal. The last written cell of the diagonal is the top-most, left-most cell of the diagonal. Likewise, first and second diagonal write patterns are defined by the order in which cells of diagonals comprising matrix 410 are read.

In this embodiment the interleaving the data (bits or symbols) are interleaved using a rectangular memory block. Blocks of M×N data bits or symbols are written diagonally into a rectangular memory block of size M×N. The data is also read diagonally from the memory block, but using the opposite diagonal direction. For example, if the data is written from top-left to bottom right, it is read from top-right to bottom-left (or from bottom-left to top right).

In this case the data is written and read on and from each diagonal. In the example shown in the sequence [S₁ . . . S₁₂] is written and [S₄, S₇, S₂, S₁₀, S₅, S₁, S₁₂, S₈, S₃, S₁₁, S₆, S₉] is read.

By reading (and writing) on diagonals, interleaver 103 provides the advantage that the resulting interleaved data do not have any periodic pattern. At the same time, the implementation complexity of this interleaver is comparable to that of a conventional block interleaver.

### Interleaver (DHS) Alternative Embodiment of Interleaver 103

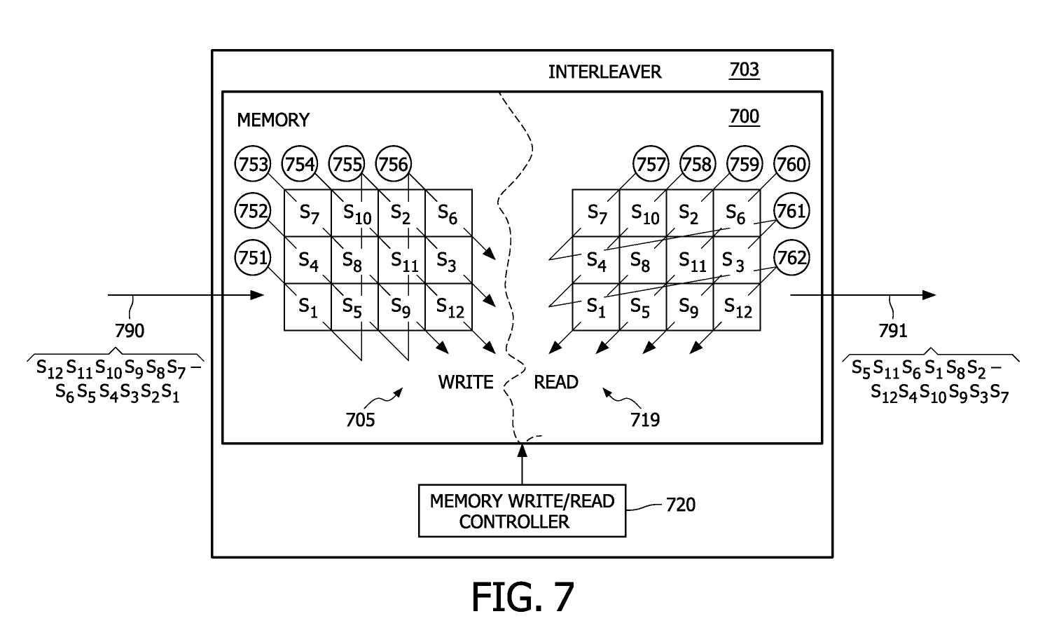

FIG. 7 is a block diagram illustrating an alternative embodiment 703 of the example interleaver 103 illustrated in FIG. 4. Interleaver 703 comprises a memory 700 coupled to a memory write/read controller 720. In this embodiment of the invention memory write read controller 720 is configured to write successive respective data portions of sequence 790 to alternating diagonals of memory 700. For example, diagonal 751 is written, and then diagonal 755 is written. Next diagonal 752 is written, followed by writing to diagonal 756 and so on.

### Symbol Mapper

Returning now to FIG. 1, regardless of the embodiment of the invention implementing interleaver 103, interleaver 103 provides interleaved bits to symbol mapper 119. Symbol mapper 119 translates the bits to symbols in accordance with one of a variety of symbol mapping techniques. In one embodiment of the invention symbol mapper 119 maps data to symbols according to a format that is selectable based upon the modulation technique employed by transmitter 100. Modulation techniques suitable for implementation by transmitter 100 and suitable for use with interleavers of the invention include, for example, Orthogonal Frequency Division Modulation (OFDM) techniques and Single Carrier Block Transmission (SCBT) techniques as well as techniques that select between OFDM and SCBT formats.

When configured to map bits to symbols according to a single-carrier format, symbol mapper 119 employs modulation techniques including, for example, quadrature phase shift keying (QPSK) techniques and M-ary quadrature amplitude modulation (M-QAM), and other suitable single carrier techniques. An alternative embodiment of symbol mapper 119 is illustrated at 130.

When configured to map bits to symbols according to a multiple-carrier format, for example OFDM, symbol mapperl30 comprises a serial-to-parallel converter 132, an adaptive modulator 134, a time domain transformer (e.g., an inverse fast Fourier transformer) 136, and a parallel-to-serial converter 138. In one variation symbol mapper 130 employs adaptive orthogonal frequency division multiplexing (adaptive-OFDM) to map bits to symbols.

In one embodiment of the example system 100 a transmission signal format selection means (not shown) determines whether symbol mapper 119 employs a single-carrier transmission format, for example SCBT, or a multi-carrier transmission format, for example OFDM (as indicated at 130) to map coded and interleaved data provided by coder/interleaver 105 to symbols.

Regardless of the particular implementation of symbol mapping, the symbols are provided by symbol mapper 119/130 to the rest of the data transmission chain, including a guard interval inserter 150, upconverter 160, high frequency transmit amplifier 170, and antenna system 180. Transmit Packet Formatter

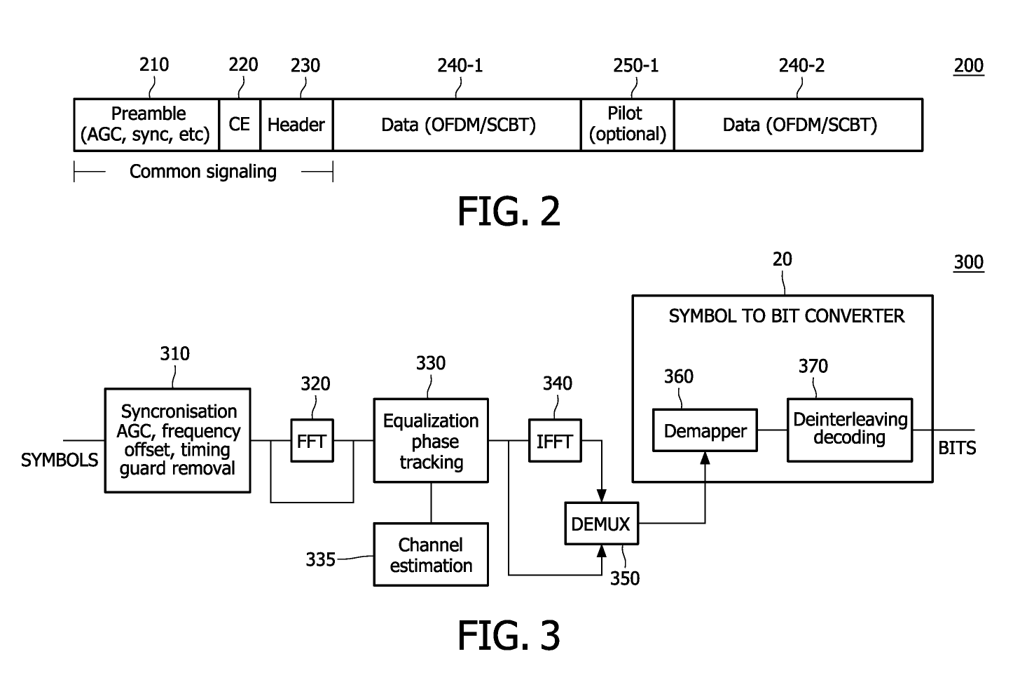

Symbol mapper 119 provides symbols to transport packet formatter 139. FIG. 2 illustrates an example structure of a data packet 200 suitable for implementation in a data transmission of communication transmitter 100. Example data packet 200 includes a preamble sequence 210, a channel equalization sequence 220, a packet header 230, at least one data segment 240-i, and at least one pilot symbol segment 250-i interleaved between data segments 240-i.

In some embodiments of the invention preamble sequence 210 includes an automatic gain control (AGC) sequence and a synchronization sequence for use by a data receiver. Beneficially, this preamble consists of repetition of a certain length sequence. Channel equalization sequence 220 comprises a predetermined sequence designed to facilitate channel equalization by a data receiver. Header 230 includes information about the data to be transmitted in the data packet, such as number of sate segments, coding type, etc.

In one embodiment a preamble & CE sequence generator 145 provides bits for the preamble and CE sequences for insertion into data provided at an input to symbol mapper 119/130. In one embodiment of the invention, a header generator supplies header bits for insertion into each data packet to be transmitted. The header bits are mapped by symbol mapper 119/130 using a transmission format matching the format used for the preamble and CE sequences.

Alternatively, a preamble & CE sequence generator 146 generates symbols for the preamble & CE sequences and those symbols are inserted in to the signal provided at an output of symbol mapper 119/130. Preamble & CE sequence generators employ one of a single-carrier transmission format for symbol mapper 119 or a multi-carrier transmission format, for example as provided the embodiment of symbol mapper 119 illustrated at 130.

In one embodiment an optional pilot symbol generator 140 generates pilot symbols to facilitate receiver detection of signals transmitted by transmitter system 100. In some embodiments a Preamble & Channel Equalizer 145 generates a sequence that is inserted into data provided by symbol mapper 119/130 at the start of each data packet. In one embodiment, preamble & Channel Equalizer sequence generator 145 generates a preamble sequence, and a sequence (e.g., a training sequence) used for channel equalization.

In order to facilitate initial communication, a first portion of each data packet 200 comprising preamble sequence 210, channel equalization sequence 220, and packet header 230 is transmitted using a common data transmission scheme. This common data transmission scheme is known a priori to every data transmitter and data receiver and is fixed. Beneficially, the common data transmission scheme employs either the same single-carrier transmission format employed by first symbol mapper 120, or the multi-carrier transmission format employed by second symbol mapper 130. In that case, the symbols for the first portion of the data packet may be generated by a suitable data symbol mapper 119. Alternatively, preamble & CE sequence generator 145 may generate the symbols for the preamble and CE sequences directly.

In an embodiment of the invention enabling selectable transmission formats, header 230 includes one or more bits which identify whether the symbols in the second portion of the data packet are mapped according to a single-carrier transmission format (e.g., SCBT), or whether the symbols in the second portion of the data packet are mapped according to a multi-carrier transmission format (e.g., adaptive OFDM). In one embodiment, a pilot sequence 250-i is inserted in-between the data segments 240-i to help a data receiver track clock/frequency offsets and channel changes.

In one embodiment of the invention an optional Guard Interval inserter periodically inserts a guard interval into the data stream to be transmitted. The guard signal inserter inserts either a cyclic prefix or a sequence of zeros in front of each block of symbols to be transmitted to create a gap interval between each block. Beneficially, this can ease channel equalization requirements at the data receiver. For example, in one embodiment 128 data symbols may be transmitted in each block, and the 32 symbols may be pre-pended to the front of each block for transmission. Alternatively, 32 zeros may be placed in front of each block of 128 symbols before transmission.

### Transmitter Front End

The formatted packets provided by formatter 139 are up-converted and amplified by a transmitter front end 159, and finally, transmitted by antenna system 180. In one embodiment, transmitter front end 159 includes an up-converter or up-sampler, a filter, and a digital-to-analog converter (not illustrated). Other convenient transmitter front end arrangements may be employed. Antenna system 180 may include one antenna, or may include multiple antennas for example for a space-division multiple access (SDMA) scheme. In general, data transmitter 100 may be included in a communication device that also includes a data receiver and a processor. The communication device may include other elements that provide functionality to the communication device. Receiver

FIG. 3 is a functional block diagram of one embodiment of a data receiver 300. Data receiver 300 includes a synchronization and guard interval removal block 310, a frequency domain transformer 320, a channel equalizer 330, a channel estimator 335, an inverse frequency domain transformer 340, a format selection means 350, a demapper 360, and a decoder/deinterleaver 370.

In one embodiment, frequency domain transformer 320 performs a fast Fourier Transform (FFT). However, other transforms may be performed instead. Also in one embodiment, inverse frequency domain transformer 340 performs an inverse fast Fourier Transform (IFFT). Again, however, other transforms may be performed instead. Furthermore, in one embodiment format selection means 350 includes a demultiplexer or switch. Although not shown in FIG. 3, in an alternate embodiment, format selection means 350 may also include a multiplexer or switch for selectively providing the output of channel equalizer 330 to one of inverse frequency domain transformer 340 and demapper 360. Decoder/deinterleaver 370 includes an error correction decoder and a data deinterleaver. The error correction decoder may decode data bits according to a predefined convolutional code, block code, or some combination thereof including a concatenated code.

Operationally, data receiver 300 functions generally as follows. Synchronization and guard interval removal block 310 receives symbols from a receive antenna system (which may include multiple antennas for space diversity) and down-converter block (not shown in FIG. 3).

Frequency domain transformer 320 receives an input signal from synchronization and guard interval removal block 310, comprising a plurality of symbols, and transforms the input signal to the frequency domain. Channel equalizer 330 equalizes the transformed signal according to an estimation of the communication channel over which the signal was received, and outputs a first signal. The channel estimation may be obtained from channel estimation block 335. Channel estimation block 335 may estimate the channel using a received channel equalization sequence such as channel equalization sequence 220 in packet 200.

Inverse frequency domain transformer 340 receives the first signal, transforms the first mapped signal to the time domain, and outputs a second signal. Format selection means 350 selects between the first signal and the second signal and outputs the selected signal to demapper 360. Beneficially, format selection means 350 selects one of the first and second signals for the first portion of each data packet (e.g., preamble, CE sequence, and header) according to a predetermined transmission format for that part of the data packet. Then, using one or more bits in the preamble, data receiver 300 is able to determine which of the two transmission formats was used for the second portion of the data packet having the data payload.

When the data transmission format is a single-carrier transmission format (e.g., SCBT), then data receiver 300 provides an SCBT signal to demapper 360. Otherwise, when the data transmission format is a multi-carrier transmission format (e.g., adaptive OFDM), then data receiver 300 receives a first signal output by channel equalizer 330 and provides the selected signal to demapper 360. Demapper 360 demaps symbols from the selected signal to output a series of bits. Finally, decoder/deinterleaver 370 applies error correction decoding to the demapped bits, and deinterleaves the corrected bits to produce an output signal.

In general, data receiver 300 may be included in a communication device that also includes a data transmitter and a processor. The communication device may include other elements that provide functionality to the communication device. Beneficially, data receiver 300 provides a very efficient implementation for receiving signals having a selectable one of two different transmission formats: a single-carrier transmission format, and a multi-carrier transmission format. Most of the blocks are common to the two formats, while inverse frequency domain transformer 340 is employed when the SCBT mode is utilized.

As noted above, depending on the data rates employed and the development of processors operating at higher and higher speeds, the various “parts” shown in FIG. 1 may be physically implemented using a software-controlled microprocessor, hard-wired logic circuits, or a combination thereof.

In embodiments of the invention wherein data transmitter 100 transmits data at any given time according to a selected one of two possible data transmission formats, data receiver includes functional blocks to determine which data transmission format is being employed so that it can be configured to receive the data. For example, data transmitter 100 communicates this information in a header of a data packet that it transmits.

### INTERLEAVING METHOD EXAMPLE 1

### Diagonal Write Operation

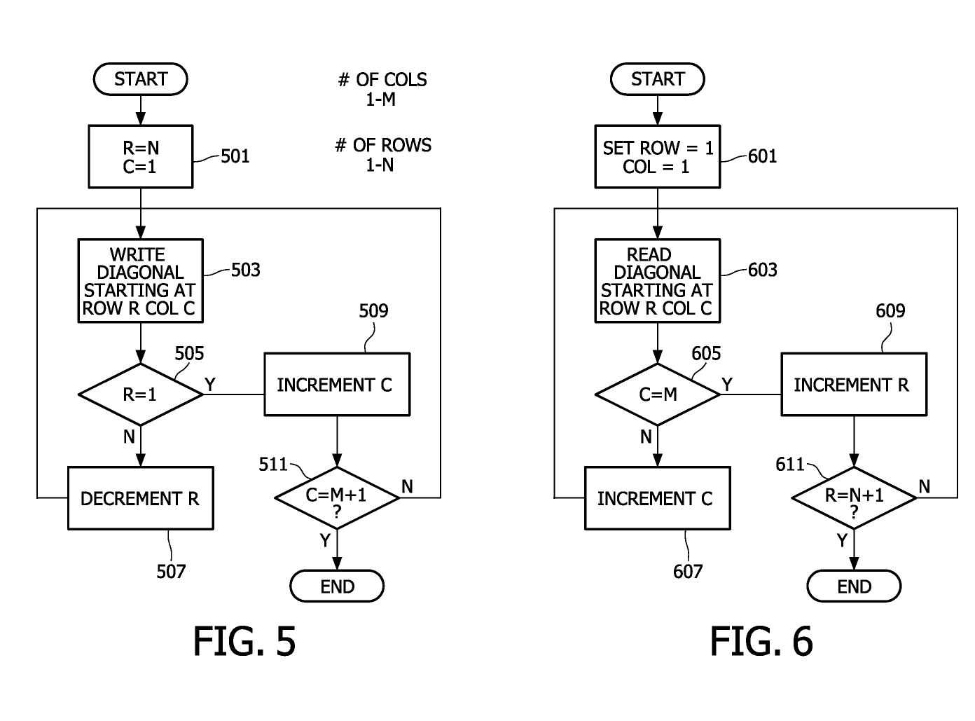

FIG. 5 is a flow chart illustrating steps of a method for generating a diagonal write sequence according to an embodiment of the invention. For ease of discussion, the method steps are described with reference to the write diagonals (451-456) illustrated in the interleaver apparatus of FIG. 4.

With reference to the flowchart of FIG. 5, the method begins by writing a first diagonal (451 of FIG. 4) with a first bit S1 of the bit sequence 490. First bit 490 is written to the cell defined by the last row N (in FIG. 4 last row N is row N) and the first column M-1 of memory 400. This cell defines a first diagonal 451 of memory 400.

The next successive bit S2 of bit sequence 490 is written to a first cell of a second diagonal (452 in FIG. 4). To define a first diagonal write direction (upper left to lower right as indicated at 407 of FIG. 4) for one embodiment of the invention, the second diagonal is defined by a first cell comprising column 1 of row N-1. To define a second diagonal direction 408 for alternative embodiments of the invention the second diagonal 452 is defined by a first cell of the second diagonal comprising column 2 of row N.

Regardless of embodiment (with respect to diagonal direction) successive respective bits of bit sequence 490 (in the example embodiment, bits S2 and S3) are written to successive respective cells of the second diagonal.

A third diagonal (for embodiments wherein a first direction is indicated at 407) is defined by writing bit S4 of bit sequence 490 to a first cell of the third diagonal, i.e., column 1 of row N-2. Successive respective bits of bit sequence 490 are written to successive respective cells of the third diagonal in the first direction and so on until all cells of the third diagonal are written. The method repeats for successive respective diagonals. In that manner a diagonal write pattern is defined.

### INTERLEAVING METHOD EXAMPLE 1—DIAGONAL READ OPERATION

FIG. 6 illustrates steps of a method for carrying out a diagonal read operation according to an embodiment of the invention. The method starts at 601 by selecting row R=1 and column C=1 of an M×N matrix. The diagonal defined by row 1 column 1 (for example, diagonal indicated at 457 of FIG. 5) is read at step 603. The method determines if C=M, in other words, whether the column read in the previous step is the last column in the matrix. If not, C is incremented at 607. The method repeats step 603 by reading the diagonal defined by column C=2, R=1 (for example diagonal indicated at 458 of FIG. 5). The method repeats steps 605 and 607 until the diagonal defined by the last column in the matrix is read. When C=M (the last column) R is incremented such that column M, Row 2 is selected at 609. The method determines if row R is the last row in the matrix. If not, the diagonal defined by column M, Row 2 (e.g. diagonal indicated at 461 in FIG. 4) is read from the matrix.

Since C has not changed, the determination if C=M will be yes and R is incremented at 609. Step 611 determines if the row R, whose diagonal was read at step 603, was the last row in the matrix. If not, the diagonal defined by C=M R=3 is read at step 603. The steps repeat until R=(R+1) indicating that the diagonal comprising the last row has been read. In that manner a diagonal read pattern is defined.

### BIT TO SYMBOL CONVERTER—EXAMPLE 1

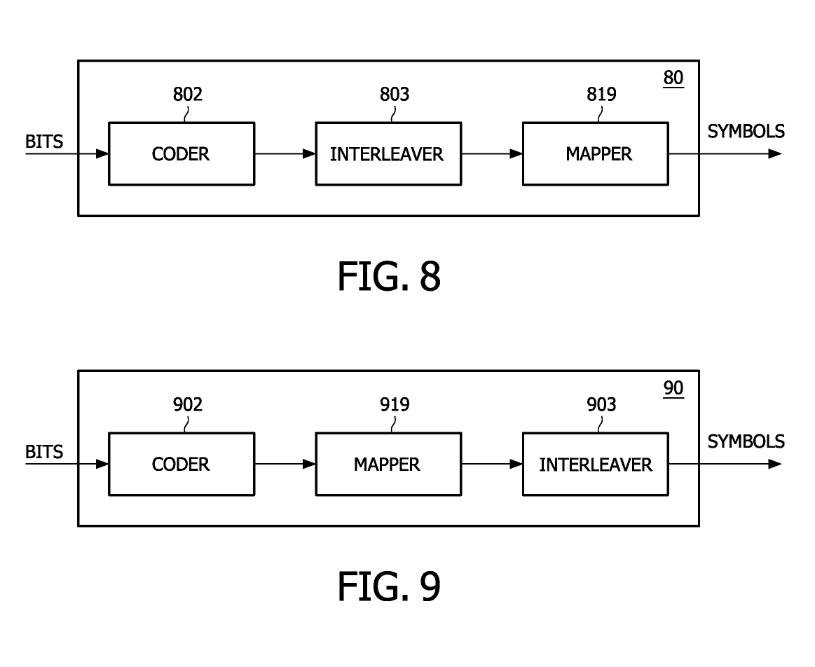

FIG. 8 is a functional block diagram of an alternative embodiment 80 of the bit to symbol converter 10 illustrated in FIG. 1. In this example embodiment an interleaver 803 is coupled to receive coded bits from a coder 802 and to provide interleaved coded bits to a mapper 819. Interleaver 802 is configured to interleave coded bits as illustrated in FIG. 4. According to an alternative embodiment of the invention, interleaver 803 is configured to interleave coded bits as illustrated in FIG. 7. The encoded interleaved bits are mapped to symbols by symbol mapper 819.

### BIT TO SYMBOL CONVERTER—EXAMPLE 2

FIG. 9 is a functional block diagram of an SCBT transmission system including a bit to symbol converter comprising an interleaver configured according to one embodiment of the invention. In this example embodiment an interleaver 803 is coupled to receive coded bits from a coder 802 and to provide interleaved coded bits to a mapper 819. Interleaver 802 is configured to interleave coded bits as illustrated in FIG. 4. According to an alternative embodiment of the invention, interleaver 803 is configured to interleave coded bits as illustrated in FIG. 7. The encoded interleaved bits are mapped to symbols by symbol mapper 819.

### BIT TO SYMBOL CONVERTER METHOD—EXAMPLE 1

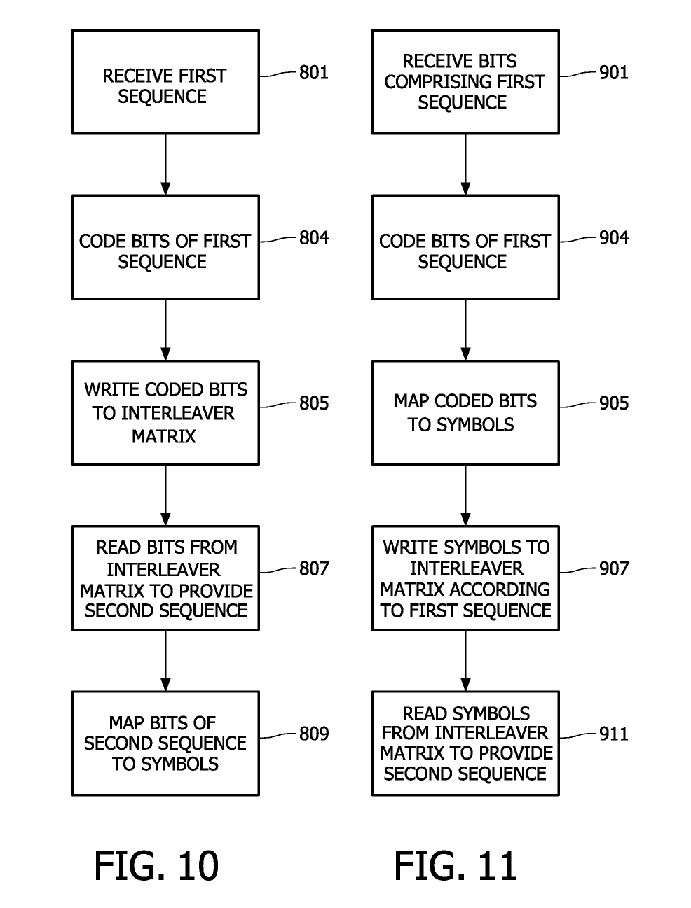

FIG. 10 is a flow chart illustrating a method of converting bits to symbols according to one example embodiment of the invention. Bits comprising data to be transmitted are received at 801. The bits are coded at 804. The coded bits are written to an interleaver matrix (example illustrated at 405/410 in FIG. 4) in accordance with a diagonal write pattern. At 807 bits are read from the interleaver matrix in accordance with a horizontal read pattern, thereby providing interleaved coded bits. The interleaved coded bits are mapped to symbols at 807.

### BIT TO SYMBOL CONVERTER METHOD—EXAMPLE 2

FIG. 11 is a flow chart illustrating a method of converting bits to symbols according to an alternative example embodiment of the invention. Bits comprising data to be transmitted are received at 901. The bits are coded at 904. The coded bits are mapped to symbols at 905. The mapped symbols are written to an interleaver matrix (example illustrated at 405/410 in FIG. 4) in accordance with a diagonal write pattern. At 907 symbols are read from the interleaver matrix in accordance with a horizontal read pattern, thereby providing interleaved symbols.

### Block Diagram

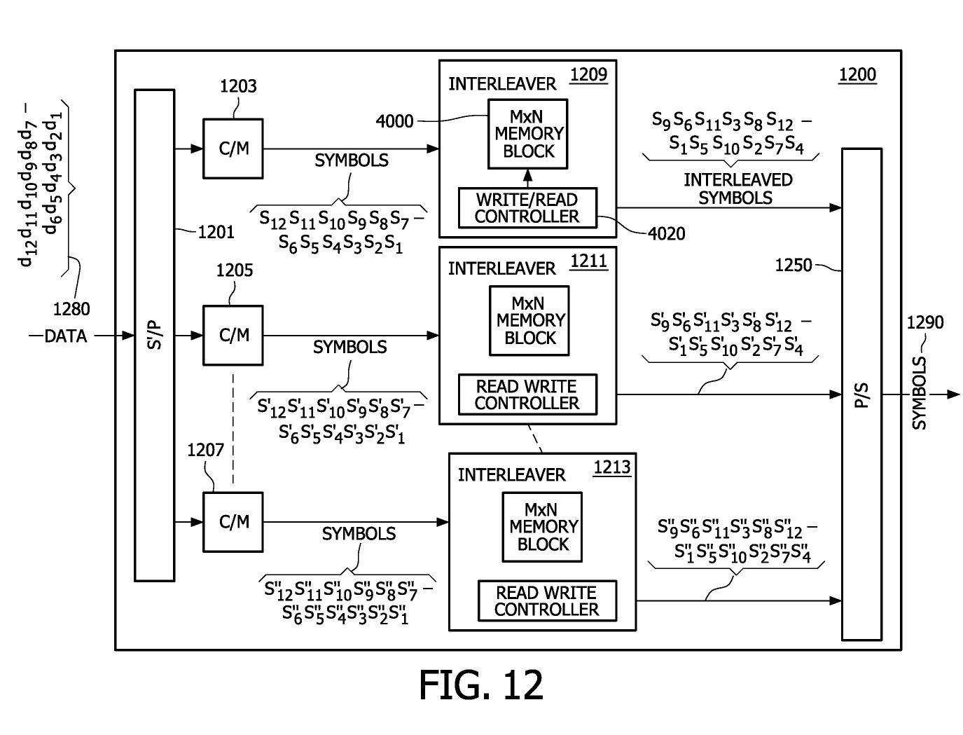

FIG. 12 is a functional block diagram of an SCBT transmission system including a bit to symbol converter 1200 configured according to an alternative embodiment of the invention. Converter 1200 comprises A serial to parallel converter 1201, a plurality of coder/mappers 1203-1207 arranged in parallel, a plurality of interleavers 1209-1213 arranged in parallel, and a parallel to serial converter 1250.

A first sequence of bits 1280 is provided to serial to parallel converter 1201. Serial to parallel converter 1201 converts sequence 1280 into a plurality of sequence portions. Each portion is provide to a corresponding one of a plurality of coder mappers (indicated at 1203-1207). Each coder mapper codes the received portion and maps the coded received portion to symbols. Each coder/mapper provides symbols to a corresponding one of a plurality of interleavers (indicated at 1209-1213.

Each interleaver writes its respective sequence of symbols to a corresponding interleaver matrix 4000-4007). Each matrix is written in accordance with a diagonal write pattern. Symbols comprising each respective matrix are read in accordance with a diagonal read pattern. Therefore each interleaver 1209-1213 provides a corresponding interleaved sequence of symbols to parallel to serial converter 1250. Parallel to serial converter 1250 merges the interleave sequences to provide a second sequence 1290 comprising interleaved symbols.

### CONVERTER—EXAMPLE 3

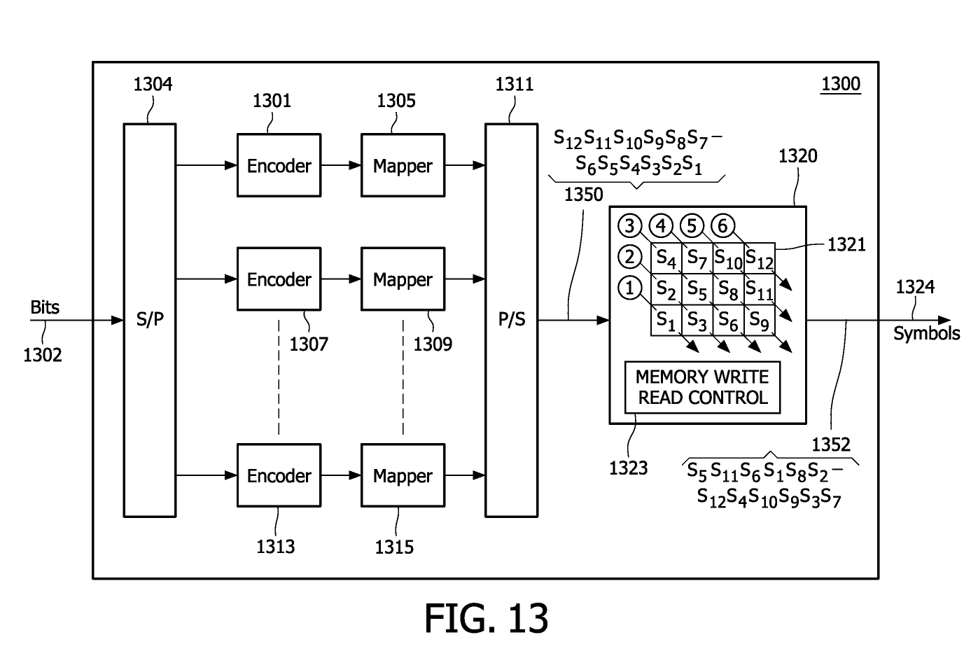

FIG. 13 is a functional block diagram of a bit to symbol converter 1300 according to an alternative embodiment of the invention. Bit to symbol converter 1300 comprises a serial to parallel converter (S/P), a plurality of encoders 1301-1313, a plurality of mappers 1305-1315, a parallel to serial converter (P/S) 1311 and an interleaver 1320. Bit to symbol converter 1330 receives a first serial bit sequence 1302 at an input of converter 1330. The bit sequence is provided to S/P 1304. S/P 1304 divides the sequence into a plurality of parallel bit sequences. For purposes of discussion three parallel bit sequences are illustrated at an output of S/P 1304 in FIG. 13. However, the invention is not limited as to the number of parallel bit sequences provided by S/P 1304.

Each bit sequence at an output of S/P 13-4 is provided to a corresponding encoder 1301-1313. Encoders 1301-1313 encode the bit sequences and provide encoded bit sequences at respective outputs. Each encoded bit sequence is provided to a corresponding mapper 1305-1315. Mappers 1305-1315 convert the bit sequences to symbol sequences and provide the symbol sequences at corresponding mapper outputs. The symbol sequences are provided to P/S 1311. P/S 1311 combines the symbol sequences to provide a first symbol sequence (e.g. sequence 1350) at an output of P/S 1311. The first symbol sequence is provided to interleaver 1320.

Interleaver 1320 comprises a diagonal interleaving matrix 1321 and controller 1323. Interleaver 1320 writes respective successive symbols of the first symbol sequence to diagonals of matrix 1321 in accordance with a diagonal write pattern. Interleaver 1320 reads symbols from matrix 1321 in accordance with a diagonal read pattern to provide a second symbol sequence, e.g., sequence 1352. In one embodiment of the invention the diagonal read pattern is an inverse pattern of the diagonal write pattern.

### CONVERTER—EXAMPLE 4

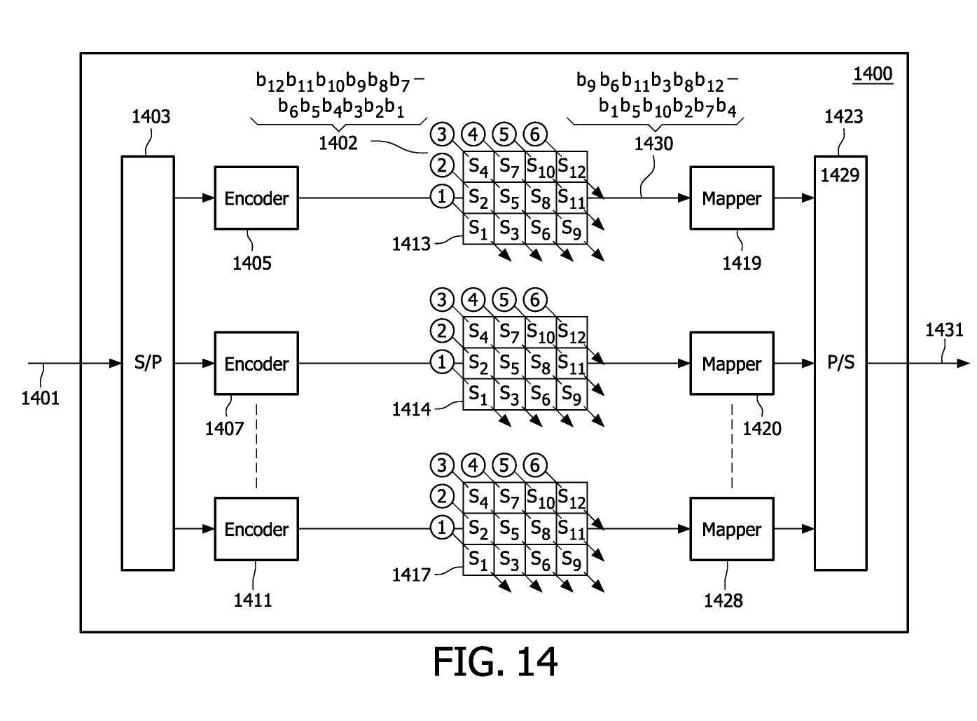

FIG. 14 is a functional block diagram of a bit to symbol converter 1400 according to an alternative embodiment of the invention. Bit to symbol converter 1400 comprises a serial to parallel converter (S/P) 1403, a plurality of encoders 1405-1411, a plurality of interleavers 1413-1417 a plurality of mappers 1419-1428, and a parallel to serial converter (P/S) 1429. Bit to symbol converter 1400 receives a first serial bit sequence 1401 at an input of converter 1400. The bit sequence is provided to an input of S/P 1403. S/P 1403 divides the sequence into a plurality of parallel bit sequences. For purposes of discussion three parallel bit sequences are illustrated at an output of S/P 1403 in FIG. 14. However, the invention is not limited as to the number of parallel bit sequences provided by S/P 1403.

Each bit sequence at an output of S/P 1403 is provided to a corresponding encoder 1405-1411. Encoders 1405-1411 encode the bit sequences and provide encoded bit sequences at respective outputs. Each encoded bit sequence is provided to a corresponding interleaver 1413-1417. For ease of discussion, interleavers 1413-1417 are represented in FIG. 14 as diagonal interleaver matrices 1413-1417. Further details regarding the various embodiments of interleavers of the invention are disclosed herein with respect to FIGS. 1-15. Interleavers 1413-1417 are configured accordingly.

Interleavers 1413-1417 comprise diagonal interleaving matrices such as illustrated in FIGS. 4 and 7. Each interleaver writes respective successive bits of a first sequence (e.g., sequence 1402) to diagonals of a matrix in accordance with a diagonal write pattern. Each interleaver reads respective successive bits from cells of its matrix in accordance with a diagonal read pattern to provide a second sequence (e.g. sequence 1430). The second sequence comprises interleaved bits of the first sequence. In one embodiment of the invention the diagonal read pattern is an inverse pattern of the diagonal write pattern. Examples of suitable diagonal read and write patterns are discussed herein with respect to FIGS. 4 and 7.

Bit sequences from interleavers 1413-1417 are provided to corresponding inputs of mappers 1419-1423. Mappers 1419-1423 map the bit sequences to symbol sequences and provide the symbol sequences at corresponding mapper outputs. The symbol sequences are provided to P/S 1429. P/S 1429 combines the symbol sequences to provide a serial symbol sequence at an output 1431 of P/S 1429.

### CONVERTER—EXAMPLE 5

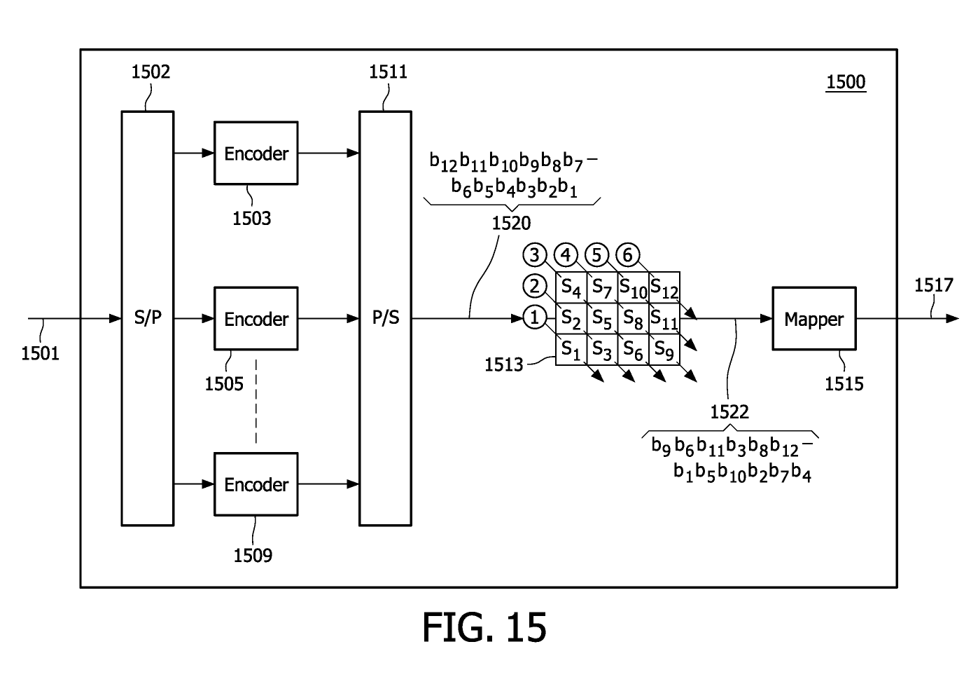

FIG. 15 is a functional block diagram of a bit to symbol converter 1500 according to an alternative embodiment of the invention. Bit to symbol converter 1500 comprises a serial to parallel converter (S/P) 1502, a plurality of encoders 1503-1509, a parallel to serial converter (P/S) 1511, an interleaver 1513 and a mapper 1515. Bit to symbol converter 1500 receives a serial bit sequence at an input 1501 of converter 1500. The bit sequence is provided to an input of S/P converter 1502. S/P 1502 divides the sequence into a plurality of parallel bit sequences. For purposes of discussion three parallel bit sequences are illustrated at an output of S/P 1502 in FIG. 15. However, the invention is not limited as to the number of parallel bit sequences provided by S/P 1502.

Each bit sequence at an output of S/P 1502 is provided to a corresponding encoder 1503-1509. Encoders 1503-1509 encode the bit sequences and provide encoded bit sequences at respective outputs. Each encoded bit sequence is provided to P/S converter 1511. P/S converter 1511 combines the bit sequences to provide a first bit sequence, for example, bit sequence 1520, at an output of P/S converter 1511.

The first bit sequence (e.g. 1520) at an output of P/S converter 1511 is provided to a corresponding interleaver 1513. For ease of discussion, interleaver 1513 is represented in FIG. 15 as a diagonal interleaver matrix. Further details regarding the various embodiments of the invention suitable for implementing diagonal matrices of interleaver 1513 are disclosed herein with respect to FIGS. 1-15.

Interleaver 1513 writes respective successive bits of first sequence 1520 to diagonals of a matrix 1513 in accordance with a diagonal write pattern. Interleaver 1513 reads respective successive bits from cells of its matrix in accordance with a diagonal read pattern to provide a second bit sequence (e.g. sequence 1522). The second sequence comprises interleaved bits of the first sequence. In one embodiment of the invention the diagonal read pattern is an inverse pattern of the diagonal write pattern. Examples of suitable diagonal read and write patterns are discussed herein with respect to FIGS. 4 and 7.

Bit sequence 1522 is provided to mapper 1515. Mapper 1515 maps the bits to symbols in accordance with a transmission format. Suitable transmission formats include, but are not limited to, OFDM and SCBT formats. Mapper 1515 provides the symbols at an output of interleaver 1500.

While the preferred embodiments are disclosed herein, many variations are possible which still remain within the concept and scope of the invention. Such variations would become clear to one of ordinary skill in the art after inspection of the specification, drawings and claims herein. The invention therefore is not to be restricted except within the spirit and scope of the appended claims.

What is claimed is:

1. A method for interleaving data portions comprising a first sequence of data portions to provide an interleaved second sequence of data portions, the method comprising steps of:
writing respective successive data portions of said encoded first sequence of data portions to a memory according to a diagonal write pattern;
reading said data portions from said memory according to a diagonal read pattern thereby interleaving data portions of said encoded first sequence of data portions to comprise said second sequence of data portions.

2. The method of claim 1 wherein each of said data portions comprises a binary digit(bit).

3. The method of claim 1 wherein each of said data portions comprises a symbol.

4. A method for converting bits representing information to be transmission in a channel, to symbols representing the information to be transmitted, the method comprising steps of:
receiving data comprising a first sequence of bits representing information to be transmitted;
encoding said first sequence of bits to provide an encoded first sequence of bits;
writing respective successive bits of said encoded first sequence of bits to a rectangular memory according to a diagonal write pattern;
reading said bits from said memory according to a diagonal read pattern to provide an encoded second sequence of bits, the encoded second sequence of bits comprising interleaved bits of said first sequence;
mapping said encoded second sequence of bits to symbols for transmission of the symbols via a data communication channel.

5. The method of claim 1 wherein said encoding step is carried out by inserting redundant bits into said first sequence of bits in accordance with a forward error correction scheme.

6. The method of claim 1 wherein said mapping step is carried out in accordance with an OFDM transmission scheme.

7. The method of claim 1 wherein said mapping step is carried out in accordance with an SCBT transmission scheme.

8. The method of claim 1 wherein said diagonal write pattern is an inverse of said diagonal read pattern.

9. The method of claim 1 wherein the step of writing respective successive bits of said encoded first sequence of bits to a rectangular memory according to a diagonal write pattern is carried out by writing to successive respective diagonals of said memory.

10. The method of claim 1 wherein the step of writing respective successive bits of said encoded first sequence of bits to a rectangular memory according to a diagonal write pattern is carried out by alternately writing to diagonals comprising a first portion of said memory and to diagonals comprising a second portion of said memory.

11. An interleaver comprising:
a memory coupled to a memory read write controller, said controller adapted to write respective successive bits of said encoded first sequence of bits to said memory according to a diagonal write pattern to define an interleaving matrix;
said controller further adapted to read said bits from said interleaving matrix according to a diagonal read pattern thereby providing an encoded second sequence of bits at an output of said interleaver, the encoded second sequence of bits comprising interleaved bits of said first sequence.

12. A bit to symbol converter comprising:
an encoder including an input for receiving data comprising a first sequence of bits to be converted to symbols, said encoder providing an encoded first sequence of bits at an encoder output;
an interleaver coupled to said encoder to receive said encoded first sequence of bits, said interleaver comprising:
a memory coupled to a memory read write controller, said controller adapted to write respective successive bits of said encoded first sequence of bits to said memory according to a diagonal write pattern;
said controller further adapted to reading said bits from said memory according to a diagonal read pattern to provide an encoded second sequence of bits at an output of said interleaver, the encoded second sequence of bits comprising interleaved bits of said first sequence;
a symbol mapper coupled to said interleaver output and configured to map said encoded second sequence of bits to symbols for transmission of said symbols via a data communication channel.

13. A method for converting data to symbols for data communication in bursty transmission channels the method comprising steps of:
receiving data comprising bits to be converted to symbols;
applying an error correction code to at least a portion of said received data;
mapping said received data to symbols;
interleaving portions of said received data carried out by steps of:
writing respective successive data portions;
reading respective
providing symbols comprising interleaved data portions for transmission in a data communication channel.

14. A data transmission system comprising:
a data encoder for respectively encoding successive bits representing information to be transmitted;
an interleaver for interleaving said bits;
a symbol mapper adapted to receive said bits and to map said bits into symbols using a transmission format;
said interleaver including a memory and a memory read write controller, said interleaver adapted to write said bits to said memory in accordance with a diagonal write pattern and further adapted to read said bits from said memory in a diagonal read pattern thereby separating;
said data transmission system thereby transmitting symbols wherein said successive bits are separated in accordance with a symbol pattern different than the diagonal write pattern .

15. The data transmission system of claim 14 wherein said symbol mapper comprises an orthogonal frequency division multiplexing (OFDM) modulator.

16. The data transmission system of claim 14 wherein said symbol mapper maps said bits to symbols in accordance with an SCBT transmission scheme.
